(19) United States
(12) Patent Application Publication
(10) Pub. No.: US 2003/0224289 A1
(43) Pub. Date: Dec. 4, 2003

(54) Photosensitive polymers and resist compositions containing the same

(75) Inventors: Sang-Jun Choi, Seoul (KR); Woo-Sung Han, Seoul (KR); Sang-Gyun Woo, Yongin-City (KR)

Correspondence Address: Anthony P. Onello, Jr., MILLS & ONELLO LLP, Suite 605, Eleven Beacon Street, Boston, MA, 02108, US

(73) Assignee: Samsung Electronics Co., Ltd.

(21) Appl. No.: 10/417,604

(22) Filed: Apr. 17, 2003

(30) Foreign Application Priority Data
May 21, 2002 (KR) 02-28227

(51) Int. Cl. G03F 7/038

(52) U.S. Cl. 430/270.1; 430/905

(57) ABSTRACT

A class of photosensitive polymers having special utility in a resist composition is disclosed, said polymers being prepared utilizing a vinyl oxy alkyl adamantane carboxylate monomer having a structural formula as shown below, the polymers having a weight average molecular weight in the range of about 3,000 to 50,000:

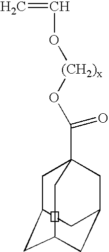

wherein x is an integer in the range of 2 to 6 inclusive. The photosensitive polymers of this invention include polymers having three or more monomer units and having the vinyl oxy alkyl adamantane carboxylate monomer polymerized with maleic acid anhydride and at least one monomer selected from the group consisting of a (meth)acrylate and norbornene derivative monomer.

### CROSS-REFERENCE TO RELATED APPLICATION

This application claims priority to Korean Patent Application No. 2002-28227 filed May 21, 2002, the contents of which are incorporated herein by reference in their entirety.

### BACKGROUND OF THE INVENTION

1. Field of the Invention

The present invention relates to a novel class of photosensitive polymers and to resist compositions containing the same. More particularly, the present invention relates to novel types of photosensitive polymers formed using a particular category of vinyl ether monomer and to resist compositions containing such polymers.

2. Description of the Related Art

A smaller sized pattern design rule of not greater than 0.2 μm is necessary in a semiconductor memory device having a capacity exceeding 1 Gbit. A photolithographic technique has been proposed in which an argon fluoride excimer laser (ArF) capable of forming 0.1 μm patterns and having a wavelength of 193 nm, which is even shorter than that of a conventional krypton fluoride excimer laser (KrF) having a wavelength of 248 nm, and a F₂ excimer laser capable of forming 0.07 μm patterns and having a wavelength of 157 nm, are used as a new type of exposure light source. According to the change in exposure light source, there is an increasing demand for developing new photoresist materials having the characteristics of transparency at a shorter wavelength of 193 nm or less; high resistance to dry etching; good adhesion to layer materials above or below; easily capable of being developed using conventional aqueous developing solutions; and excellent in annealing effect during baking.

However, compared to the conventional KrF resist materials, known ArF resist materials pose many problems for practical use. For example, poly(methyl methacrylate-t-butyl methacrylate-methacrylic acid), a terpolymer commercially available from IBM Corp., is weak in resistance to dry etching. A polymer containing 2-methyl-2-adamantyl methacrylate (SPIE, 2438, 423 (1995) Fujitsu Co., Ltd.) fails to overcome the disadvantages in that this polymer still has poor resistance to dry etching and weak adhesion to underlying layer materials.

These conventional resist polymers also have a glass transition temperature of 200° C. or more due to the structural characteristics of their backbones. As a result, it is difficult to achieve an annealing effect for eliminating a free volume from the resist layer formed of the polymer with the above structure during baking. Accordingly, the resist layer has poor environmental resistance. As a result, when the polymer contacts a basic contaminant in the atmosphere, acid (H⁺) generated from a photoacid generator (PAG) by exposure cannot participate in acidolysis in the polymer and is quenched. Also, the acid is easily diffused into a non-exposed portion thereby producing a photoresist pattern having a poor profile, such as, for example, a T-top profile.

### SUMMARY OF THE INVENTION

The present invention is generally directed to photosensitive polymers or polymer compositions which have a glass transition temperature high enough to acquire an annealing effect during baking while also satisfying requirements as a main component of a resist material.

The present invention is also directed to resist compositions containing such polymers which are suitable for an exposure light source having a shorter wavelength of 193 nm or less.

According to one aspect of the present invention, there is provided a photosensitive polymer or polymer composition which is prepared using a vinyl oxy alkyl adamantane carboxylate monomer and having a weight average molecular weight in the range of about 3,000 to 50,000.

The photosensitive polymers or polymer compositions of this invention may in certain embodiments be polymers prepared using three or more monomer units in which the vinyl oxy alkyl adamantane carboxylate monomer is polymerized with maleic acid anhydride and at least one monomer selected from the group consisting of adamantyl meth acrylate, norbornene derivative monomer, and comparable materials as described herein.

According to another aspect of the present invention, there is provided a resist composition including at least one polymer selected from the above photosensitive polymers and about 1-15% by weight based on the weight of the photosensitive polymer of a photoacid generator (PAG). In some preferred embodiments, the PAG is selected from the group consisting of triarylsulfonium salts, diaryliodonium salts, sulfonates, and mixtures of two or more of these compounds.

The resist composition may in some preferred embodiments further include an organic base. The organic base is preferably present in an amount of about 0.01 to 2% by weight based on the weight of the photosensitive polymer.

### DETAILED DESCRIPTION OF PREFERRED EMBODIMENTS

A particular class of photosensitive polymers or polymer compositions and resist compositions including at least one of the polymers of that class are provided and described. Also described is a preferred photolithography process using a resist composition in accordance with this invention. This invention may, however, be embodied in many different forms, and a number of representative embodiments are provided herein to better fully convey the scope of the invention to those skilled in the art. In chemical formulas, the same characters are used to denote the same functional groups.

A photosensitive polymer or polymer composition prepared according to one embodiment of the present invention includes about 10 to 40 mole % of a vinyl oxy alkyl adamantane carboxylate monomer, and thus has vinyl ether as a main component of its backbone. It has been found in accordance with this invention that the vinyl ether backbone is more flexible than a conventional alicyclic hydrocarbon backbone, and this feature contributes to lowering the glass transition temperature of the photosensitive polymer. A C₂-C₆ alkyl group connecting the vinyl ether with adamantane ester has been found to further increase the flexibility of the photosensitive polymer. A vinyl oxy alkyl adamantane carboxylate monomer according to this invention can be expressed by the following Formula 1:

[Formula 1]

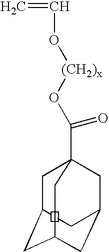

wherein x is an integer in the range of 2 to 6 inclusive.

Since the vinyl oxy alkyl adamantane carboxylate (herein VOAAC) monomer has the chemical property of being electron-deficient, it is able to form an alternating polymer with maleic acid which has an electron surplus. The alternating VOACC-maleic acid polymer structure bonds with other monomers and easily forms more complex polymers, including terpolymers, having three or more monomer units. Preferably, the alternating VOACC-maleic acid polymer is polymerized with at least one monomer selected from the group consisting of acid-labile (meth)acrylate and acid-labile norbornene derivative monomer to form a complex polymer comprising three or more monomer units, such as terpolymer, tetrapolymer and the like.

A complex polymer having three or more monomer units, such as terpolymer, tetrapolymer and the like, in accordance with this invention can be expressed by chemical formulas as illustrated by the following Formulas 2-4:

[Formula 2]

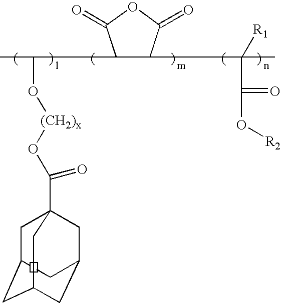

In Formula 2 above, x is an integer in the range of 2 to 6 inclusive; R₁ is a hydrogen atom or a methyl group; R₂ is a C₄-C₂₀ acid-labile hydrocarbon group; the quantity represented by the expression l/(l+m+n) is in the range of about 0.1 to 0.4; the quantity represented by the expression m/(l+m+n) is in the range of about 0.1 to 0.5; the quantity represented by the expression n/(l+m+n) is in the range of about 0.1 to 0.4, and the weight average molecular weight of the photosensitive polymer is in the range of about 3,000 to 50,000. Examples of the C₄-C₂₀ acid-labile hydrocarbon group in Formula 2 include for example t-butyl, tetrahydropyranyl and 1-ethoxy ethyl. In the case where the C₄-C₂₀ acid-labile hydrocarbon group is selected from a C₆-C₂₀ acid-labile alicyclic hydrocarbon group, it has been found that the resulting photosensitive polymer exhibits improved dry etching resistance. Suitable examples of the C₆-C₂₀ acid-labile alicyclic hydrocarbon group include 2-methyl-2-adamantyl, 2-ethyl-2-adamantyl, 2-propyl-2-adamantyl, 8-methyl-8-tricyclodecyl, and 8-ethyl-8-tricyclodecyl.

[Formula 3]

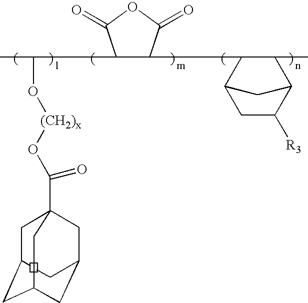

In Formula 3 above x is an integer in the range of 2 to 6 inclusive; R₃ is a C₄-C₂₀ acid-labile ester group; the quantity represented by the expression l/(l+m+n) is in the range of about 0.1 to 0.4; the quantity represented by the expression m/(l+m+n) is in the range of about 0.3 to 0.5; the quantity represented by the expression n/(l+m+n) is in the range of about 0.2 to 0.5; and the weight average molecular weight of the photosensitive polymer is in the range of about 3,000 to 30,000.

Examples of the C₄-C₂₀ acid-labile ester group include t-butyl ester, tetrahydropyranyl ester and 1-ethoxy ethyl ester. In the case where the C₄-C₂₀ group is selected from a C₆-C₂₀ acid-labile alicyclic hydrocarbon ester group, it has been found that the resulting photosensitive polymer exhibits improved dry etching resistance. Suitable examples of the C₆-C₂₀ acid-labile alicyclic hydrocarbon group include 2-methyl-2-adamantyl ester, 2-ethyl-2-adamantyl ester, 2-propyl-2-adamantyl ester, 8-methyl-8-tricyclodecyl ester, and 8-ethyl-8-tricyclodecyl ester.

[Formula 4]

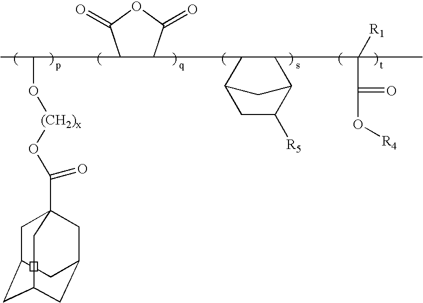

In Formula 4 above, x is an integer in the range of 2 to 6 inclusive; R₁ is a hydrogen atom or a methyl group; R₄ is a C₁-C₂₀ hydrocarbon group or a C₄-C₂₀ acid-labile hydrocarbon group; R₅ is a hydrogen atom, carboxylic acid, or a group selected from halide, hydroxy, nitrile, alkyl, alkoxy, sulfonate or a C₄-C₂₀ acid-labile ester; the quantity represented by the expression p/(p+q+s+t) is in the range of about 0.1 to 0.3; the quantity represented by the expression q/(p+q+s+t) is in the range of about 0.2 to 0.5; the quantity represented by the expression s/(p+q+s+t) is in the range of about 0.1 to 0.3; the quantity represented by the expression t/(p+q+s+t) is in the range of about 0.1 to 0.4; and the weight average molecular weight of the photosensitive polymer is in the range of about 3,000 to 30,000.

Suitable examples of the C₄-C₂₀ acid-labile hydrocarbon group and the C₄-C₂₀ acid-labile ester group include, for example, the specific groups enumerated in Formulas 2 and 3 above. A photosensitive polymer according to the present invention, as described above, can be obtained by known radical polymerization processes, e.g., bulk polymerization or solution polymerization. As the polymerization initiator, general radical initiators, such as azobisisobutyronitrile (AIBN) may be used. During solution polymerization, a solvent such as THF, dioxane, ethylacetate, dichloromethane or cyclohexane may be used. As previously noted, the preferred weight average molecular weight of photosensitive polymers in accordance with this invention is in the range of about 3,000 to 50,000.

To prepare a resist composition according to exemplary embodiments of the present invention, the polymers synthesized as described above are dissolved in various types of solvents such as propylene glycol monomethyl ether acetate (PGMEA), ethyl lactate or cyclohexanone together with a suitable photoacid generator (PAG).

The PAG is preferably contained in a resist composition according to this invention in an amount ranging from about 1 to 15% by weight based on the weight of the photosensitive polymer. Suitable PAGs include triarylsulfonium salts, diaryliodonium salts, sulfonate, and mixtures thereof.

Specific examples of the PAG component of the resist compositions of this invention include triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitro benzyl sulfonate, pyrogallol tris(alkyl-sulfonate), norbornene-dicarboximide triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene dicarboximide nonaflate, triphenylsulfonium perfluorooctanesulfonate, diphenyliodonium perfluorooctanesulfonate, methoxydiphenyliodonium perfluorooctane sulfonate, N-hydroxysuccinimide perfluorooctanesulfonate, or norbornene dicarboximide perfluorooctanesulfonate, and mixtures thereof.

Preferably, a resist composition according to preferred embodiments of the present invention further includes about 0.01 to 2% by weight based on the weight of the photosensitive polymer of an organic base. Suitable organic bases for this purpose include tertiary amines. Specific examples of the organic base component of the resist compositions of this invention include triethylamine, triisobutylamine, triisooctylamine, triisodecylamine, diethanolamine, triethanolamine and mixtures thereof. The organic base is added for preventing a pattern deformation, which results from an unexpected acidolysis caused by the acid generated at the exposed regions and then diffused into the unexposed regions after exposure.

Also, a resist composition according to preferred embodiments of the present invention includes from about 30 to 200 ppm of an organic or base surfactant, which functions to allow the resist composition to be uniformly coated on a substrate.

To adjust the overall dissolution speed of the resist, the resist composition of exemplary embodiments further includes from about 5 to 25% by weight based on the weight of the photosensitive polymer of a dissolution inhibitor.

For a lithography process, a resist solution prepared according to this invention is first filtered twice using a 0.2 μm membrane filter to obtain the resist composition. The obtained resist composition is then utilized according to the following process to obtain a pattern.

A bare silicon wafer or a silicon wafer having a layer to be patterned thereon is prepared and treated with hexamethyldisilazane (HMDS). Thereafter, the silicon wafer layer is coated with the resist composition to a thickness of approximately 0.2 to 0.7 μm to form a resist layer.

The silicon wafer having the resist layer is pre-baked at a temperature in the range of about 90 to 180° C., preferably 120 to 140° C., for approximately 60 to 120 seconds to remove a solvent, followed by exposure to a light source using an exposure light source having a wavelength of 193 nm or less. When using a light source having a wavelength of 193 nm or less, exposure is preferably performed at a dose of about 5 to 100 mJ/cm². Next, post-exposure baking (PEB) is performed at a temperature in the range about 90 to 180° C., preferably 110 to 140° C., for approximately 60 to 120 seconds to cause acidolysis at an exposed portion of the resist layer. As a result, acidolysis actively occurs at the exposed portion, allowing the exposed portion to exhibit very high solubility to a developing solution including 2.38 wt % tetramethylammonium hydroxide (TMAH). Thus, during development, the exposed portion is dissolved well for removal.

The silicon wafer or the wafer layer to be patterned is then etched by a special etching gas, such as plasma, e.g., a halogen or a CₓF_{y} gas (x and y being integers), using the resultant resist pattern as an etching mask. Subsequently, the resist pattern remaining on the wafer is removed by ashing and a wet process using a stripper, thereby forming a desired pattern. The resist composition according to the present invention has been found to demonstrate significantly better etching resistance than conventional resist materials because it includes a polymer having an adamantyl group.

Also, because conventional polymers have very high glass transition temperatures of 200° C. or higher due to their rigid backbones, many problems may have been caused during the processing steps. By contrast, the photosensitive polymers included in resist compositions according to exemplary embodiments of this invention have appropriate glass transition temperatures in the range of about 130 to 180° C. Thus, the resist layer formed using a photosensitive polymer according to embodiments of the present invention has a sufficient annealing effect during baking, thereby reducing its dynamic volume. Accordingly, the environmental resistance of the resist layer improvesthereby enhancing lithography performance.

Further illustrative exemplary embodiments of the present invention will be described below in detail and with reference to the following examples and synthesis examples. It is noted that reagents used for explaining the invention are generally commercially available, and most are available from Aldrich Chemical Co.

### EXAMPLE OF SYNTHESIS OF AN ADAMANTANE CARBOXYLATE MONOMER

### Synthesis of 2-vinyl oxy ethyl-1-adamantane carboxylate

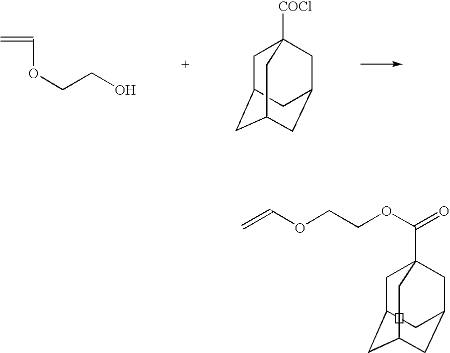

19.4 g (0.22 mol) of ethylene glycol vinyl ether and 25 g of triethyl amine were dissolved in 300 mL tetrahydrofuran (THF) to be put in a 500 mL-three-neck flask, and 40 g (0.2 mol) of 1-adamantancarbonyl chloride was then slowly added thereto dropwise. The mixture was then reacted at room temperature for approximately 12 hours. After the reaction was completed, the reactant was dropped into excess water, neutralized with a weak chloric acid solution, and extracted with an appropriate amount of diethyl ether. An organic layer was then separated, followed by vacuum-drying with sulfuric magnesium, to give the monomer 2-vinyl oxy ethyl-1-adamantane carboxylate with a yield of about 70%.

### EXAMPLES OF SYNTHESIS OF PHOTOSENSITIVE ADAMANTANE TERPOLYMERS

### Terpolymer Synthesis Example 1

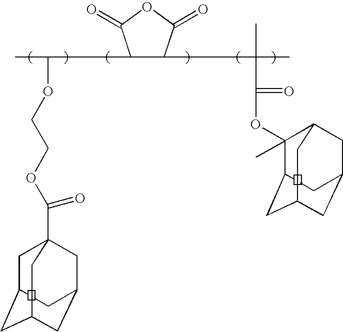

2.5 g (10 mmol) of 2-vinyl oxy ethyl-1-adamantane carboxylate as synthesized in the above Synthesis Example, 1.0 g (10 mmol) of maleic anhydride, 2.35 g (10 mmol) of 2-methyl-2-adamantyl methacrylate and 0.25 g (5 mol %) of AIBN were dissolved in 12 g of THF, and purged with nitrogen gas, followed by polymerizing at 65° C. for approximately 20 hours.

After the polymerization was completed, the reactant was dropped into excess isopropyl alcohol for precipitation. The precipitate was filtered, dissolved again in an appropriate amount of THF and then reprecipitated in excess n-hexane, followed by drying in a vacuum oven maintained at about 50° C. for about 24 hours to obtain the desired adamantane terpolymer having the above formula with a yield of about 70%.

The weight average molecular weight and polydispersity (Mw/Mn) of the obtained terpolymer were 9,700 and 1.7, respectively.

### Terpolymer Synthesis Example 2

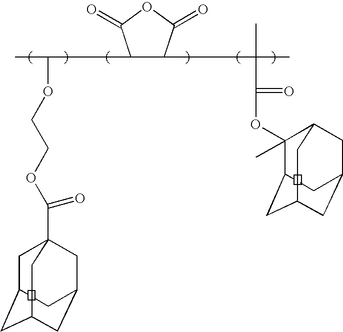

A terpolymer having the above formula was obtained by carrying out polymerization in the same manner as described above in Terpolymer Synthesis Example 1, except that 2.2 g (10 mmol) of a 2-methyl-2-adamantyl acrylate was used instead of the 2-methyl-2-adamantyl methacrylate (yield: 68%).

The weight average molecular weight and polydispersity (Mw/Mn) of the obtained terpolymer were 10,700 and 1.9, respectively.

### Terpolymer Synthesis Example 3

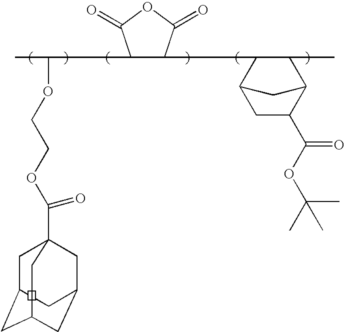

2.0 g (10 mmol) of 2-vinyl oxy ethyl-1-adamantane carboxylate, 2.0 g (20 mmol) of maleic anhydride, 2.0 g (10 mmol) of 5-norbornene-2-carboxylate and 0.25 g (5 mol %) of AIBN were dissolved in 14 g of THF, followed by polymerizing in the same manner as in Terpolymer Synthesis Example 1, thereby obtaining the desired terpolymer having the above formula with a yield of about 55%.

The weight average molecular weight and polydispersity (Mw/Mn) of the obtained terpolymer were 8,600 and 1.9, respectively.

### EXAMPLE OF SYNTHESIS OF PHOTOSENSITIVE ADAMANTANE TETRAPOLYMER

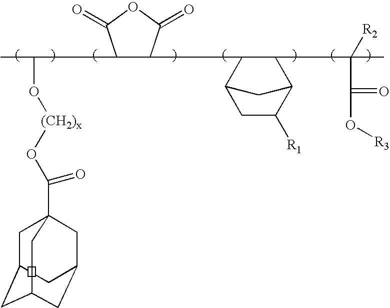

2.5 g (10 mmol) of 2-vinyl oxy ethyl-1-adamantane carboxylate, 1.5 g (15 mmol) of maleic anhydride, 0.5 g (5 mmol) of norbornene, 3.5 g (15 mmol) of 2-methyl-2-adamantyl methacrylate and 5 mol % of AIBN were dissolved in 16 g of THF, followed by polymerizing in the same manner as in Terpolymer Synthesis Example 1, thereby obtaining the desired tetrapolymer having the above formula with a yield of about 70%.

The weight average molecular weight and polydispersity (Mw/Mn) of the obtained tetrapolymer were 9,800 and 1.8, respectively.

Preparation of Resist Compositions and Photolithography Processes Using the Same

Each of the adamantane polymers synthesized in the above described Synthesis Examples was formulated into a resist composition according to this invention using the following procedure: 1.0 g of the adamantane polymer and 5-20 mg of triphenylsulfonium triflate and 10-20 mg of triphenylsulfonium nonaflate as a photoacid generator (PAG) were dissolved in 8.0 g of a cyclohexanone or PGMEA solvent, and 2 mg of triisobutylamine as an organic base was added thereto for complete dissolution, followed by filtering using a 0.2 μm membrane filter, thereby yielding each resist composition. Silicon (Si) wafers treated with an anti-reflective coating were coated with each of the obtained resist compositions to a thickness of approximately 0.3 μm.

Thereafter, each coated wafer was soft-baked at a temperature of 120 to 140° C. for approximately 60 to 90 seconds, then was exposed using an ArF excimer laser stepper (NA=0.6, σ=0.75), followed by performing post-exposure baking at 110 to 140° C. for approximately 60 to 90 seconds.

Next, development was performed using 2.38% by weight of a tetramethylammonium hydroxide (TMAH) solution to form a resist pattern on each wafer.

The results showed that a 0.16 μm line-and-space pattern was obtained at an exposure dose of approximately 8 to 25 mJ/cm².

Because a photosensitive polymer according to the present invention includes a vinyl ether monomer, it is more flexible than a conventional photosensitive polymer having a relatively rigid alicyclic hydrocarbon backbone, thereby contributing to lowering the glass transition temperature of the photosensitive polymers of this invention. Also, a C₂-C₆ alkyl group connecting the vinyl ether with adamantane ester further increases the flexibility of the photosensitive polymers of this invention. Thus, a photoresist layer formed of a resist material which includes a photosensitive composition according to the present invention as a main component has a sufficient annealing effect during baking, thereby reducing the dynamic volume in the resist layer. Thus, environmental resistance is enhanced even at post-exposure delay (PED). Therefore, resist compositions based on photosensitive polymers according to the present invention exhibit excellent lithography performance so that such compositions can be advantageously used for the manufacture of next generation semiconductor devices with increasingly demanding performance criteria. Further, the glass transition temperatures of the photosensitive polymers according to the present invention can be further lowered by careful selection of different kinds of monomers to be bonded to the vinyl ether monomer. Dry etching resistance and contrast characteristics of resulting resist compositions thereof can thereby be further improved. Other advantages of the photosensitive polymers according to the present invention are that monomers used for the manufacture of these polymers are relatively inexpensive and can be obtained with relatively high yields.

Having described the invention, what is claimed is:

1. A photosensitive polymer prepared utilizing a vinyl oxy alkyl adamantane carboxylate monomer having the following formula, said polymer having a weight average molecular weight in the range of about 3,000 to 50,000: 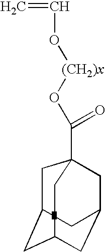
wherein x is an integer in the range of 2 to 6 inclusive.

2. A photosensitive polymer according to claim 1, wherein said photosensitive polymer consists essentially of a terpolymer having the formula: 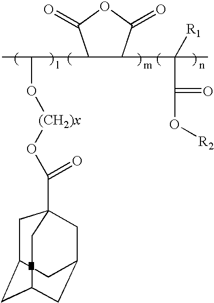
wherein x is an integer in the range of 2 to 6 inclusive; R₁ is a hydrogen atom or a methyl group; R₂ is a C₄-C₂₀ acid-labile hydrocarbon group; the quantity represented by the expression l/(l+m+n) is in the range of about 0.1 to 0.4; the quantity represented by the expression m/(l+m+n) is in the range of about 0.1 to 0.5; the quantity represented by the expression n/(l+m+n) is in the range of about 0.1 to 0.4; and the weight average molecular weight of the photosensitive polymer is in the range of about 3,000 to 50,000.

3. A photosensitive polymer according to claim 2, wherein said C₄-C₂₀ acid-labile hydrocarbon group is selected from the group consisting of t-butyl, tetrahydropyranyl, and 1-ethoxy ethyl.

4. A photosensitive polymer according to claim 2, wherein said C₄-C₂₀ acid-labile hydrocarbon group is a C₆-C₂₀ acid-labile alicyclic hydrocarbon group selected from the group consisting of 2-methyl-2-adamantyl, 2-ethyl-2-adamantyl, 2-propyl-2-adamantyl, 8-methyl-8-tricyclodecyl, and 8-ethyl-8-tricyclodecyl.

5. A photosensitive polymer according to claim 1, wherein said photosensitive polymer consists essentially of a terpolymer having the formula: 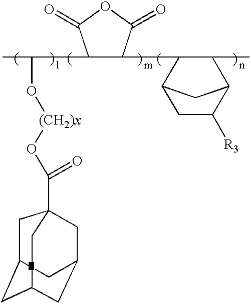
wherein x is an integer in the range of 2 to 6 inclusive; R₃ is a C₄-C₂₀ acid-labile ester group; the quantity represented by the expression l/(l+m+n) is in the range of about 0.1 to 0.4; the quantity represented by the expression m/(l+m+n) is in the range of about 0.3 to 0.5; the quantity represented by the expression n/(l+m+n) is in the range of about 0.2 to 0.5; and the weight average molecular weight of the photosensitive polymer is in the range of about 3,000 to 30,000.

6. A photosensitive polymer according to claim 5, wherein said C₄-C₂₀ acid-labile ester group is selected from the group consisting of t-butyl ester, tetrahydropyranyl ester, and 1-ethoxy ethyl ester.

7. A photosensitive polymer according to claim 5, wherein said C₄-C₂₀ group is a C₆-C₂₀ acid-labile alicyclic hydrocarbon ester group selected from the group consisting of 2-methyl-2-adamantyl ester, 2-ethyl-2-adamantyl ester, 2-propyl-2-adamantyl ester, 8-methyl-8-tricyclodecyl ester, and 8-ethyl-8-tricyclodecyl ester.

8. A photosensitive polymer according to claim 1, wherein said photosensitive polymer consists essentially of a tetrapolymer having the formula: 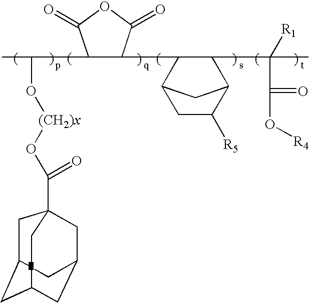
wherein x is an integer in the range of 2 to 6 inclusive, R₁ is a hydrogen atom or a methyl group; R₄ is a C₁-C₂₀ hydrocarbon group or a C₄-C₂₀ acid-labile hydrocarbon group; R₅ is a hydrogen atom, carboxylic acid, or a group selected from halide, hydroxy, nitrile, alkyl, alkoxy, sulfonate or a C₄-C₂₀ acid-labile ester; the quantity represented by the expression p/(p+q+s+t) is in the range of about 0.1 to 0.3,; the quantity represented by the expression q/(p+q+s+t) is in the range of about 0.2 to 0.5; the quantity represented by the expression s/(p+q+s+t) is in the range of about 0.1 to 0.3; the quantity represented by the expression t/(p+q+s+t) is in the range of about 0.1 to 0.4; and the weight average molecular weight of the photosensitive polymer is in the range of about 3,000 to30,000.

9. A photosensitive polymer according to claim 8, wherein R₄ is a C₄-C₂₀ acid-labile hydrocarbon group selected from the group consisting of t-butyl, tetrahydropyranyl, and 1-ethoxy ethyl, and R₅ is a C₄-C₂₀ acid-labile ester group selected from the group consisting of t-butyl ester, tetrahydropyranyl ester, and 1-ethoxy ethyl ester.

10. A photosensitive polymer according to claim 8, wherein R₄ is a C₄-C₂₀ acid-labile hydrocarbon group which is a C₆-C₂₀ alicyclic hydrocarbon group selected from the group consisting of 2-methyl-2-adamantyl, 2-ethyl-2-adamantyl, 2-propyl-2-adamantyl, 8-methyl-8-tricyclodecyl, and 8-ethyl-8-tricyclodecyl, and R₅ is a C₄-C₂₀ acid-labile ester group which is a C₆-C₂₀ acid-labile alicyclic hydrocarbon ester group selected from the group consisting of 2-methyl-2-adamantyl ester, 2-ethyl-2-adamantyl ester, 2-propyl-2-adamantyl ester, 8-methyl-8-tricyclodecyl ester, and 8-ethyl-8-tricyclodecyl ester.

11. A resist composition consisting essentially of:
(a) a photosensitive polymer prepared utilizing a vinyl oxy alkyl adamantane carboxylate monomer having the following formula, said polymer having a weight average molecular weight in the range of about 3,000 to 50,000: 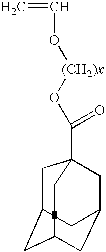
wherein x is an integer in the range of 2 to 6 inclusive; and,.
(b) about 1 to 15% by weight based on the weight of the photosensitive polymer of a photoacid generator (PAG).

12. A resist composition according to claim 11, wherein said photosensitive polymer consists essentially of a terpolymer having the formula: 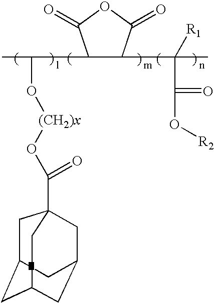
wherein x is an integer in the range of 2 to 6 inclusive, R₁ is a hydrogen atom or a methyl group; R₂ is a C₄-C₂₀ acid-labile hydrocarbon group; the quantity represented by the expression l/(l+m+n) is in the range of about 0.1 to 0.4; the quantity represented by the expression m/(l+m+n) is in the range of about 0.1 to 0.5; the quantity represented by the expression n/(l+m+n) is in the range of about 0.1 to 0.4; and the weight average molecular weight of the photosensitive polymer is in the range of about 3,000 to 50,000.

13. A resist composition according to claim 12, wherein said C₄-C₂₀ acid-labile hydrocarbon group is selected from the group consisting of t-butyl, tetrahydropyranyl, and 1-ethoxy ethyl.

14. A resist composition according to claim 12, wherein said C₄-C₂₀ acid-labile hydrocarbon group is a C₆-C₂₀ acid-labile alicyclic hydrocarbon group selected from the group consisting of 2-methyl-2-adamantyl, 2-ethyl-2-adamantyl, 2-propyl-2-adamantyl, 8-methyl-8-tricyclodecyl, and 8-ethyl-8-tricyclodecyl.

15. A resist composition according to claim 11, wherein said polymer consists essentially of a terpolymer having the formula: 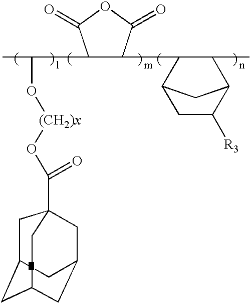
wherein x is an integer in the range of 2 to 6 inclusive; R₃ is a C₄-C₂₀ acid-labile ester group; the quantity represented by the expression l/(l+m+n) is in the range of about 0.1 to 0.4; the quantity represented by the expression m/(l+m+n) is in the range of about 0.3 to 0.5; the quantity represented by the expression n/(l+m+n) is in the range of about 0.2 to0.5; and the weight average molecular weight of the photosensitive polymer is in the range of about 3,000 to 30,000.

16. A resist composition according to claim 15, wherein said C₄-C₂₀ acid-labile ester group is selected from the group consisting of t-butyl ester, tetrahydropyranyl ester, and 1-ethoxy ethyl ester.

17. A resist composition according to claim 15, wherein said C₄-C₂₀ group is a C₆-C₂₀ acid-labile alicyclic hydrocarbon ester group selected from the group consisting of 2-methyl-2-adamantyl ester, 2-ethyl-2-adamantyl ester, 2-propyl-2-adamantyl ester, 8-methyl-8-tricyclodecyl ester, and 8-ethyl-8-tricyclodecyl ester.

18. A resist composition according to claim 11, wherein said polymer consists essentially of a tetrapolymer having the formula: 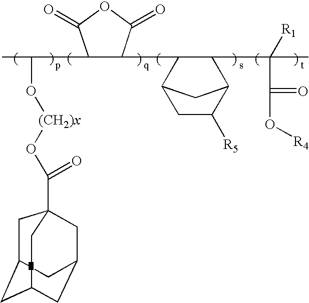
wherein x is an integer in the range of 2 to 6 inclusive; R₁ is a hydrogen atom or a methyl group; R₄ is a C₁-C₂₀ hydrocarbon group or a C₄-C₂₀ acid-labile hydrocarbon group; R₅ is a hydrogen atom, carboxylic acid, or a group selected from halide, hydroxy, nitrile, alkyl, alkoxy, sulfonate or a C₄-C₂₀ acid-labile ester; the quantity represented by the expression p/(p+q+s+t) is in the range of about 0.1 to 0.3; the quantity represented by the expression q/(p+q+s+t) is in the range of about 0.2 to 0.5; the quantity represented by the expression s/(p+q+s+t) is in the range of about 0.1 to 0.3; the quantity represented by the expression t/(p+q+s+t) is in the range of about 0.1 to 0.4; and the weight average molecular weight of the photosensitive polymer is in the range of about 3,000 to 30,000.

19. A resist composition according to claim 18, wherein R₄ is a C₄-C₂₀ acid-labile hydrocarbon group selected from the group consisting of t-butyl, tetrahydropyranyl, and 1-ethoxy ethyl, and R₅ is a C₄-C₂₀ acid-labile ester group selected from the group consisting of t-butyl ester, tetrahydropyranyl ester, and 1-ethoxy ethyl ester.

20. A resist composition according to claim 18, wherein R4 is a C4-C₂₀ acid-labile hydrocarbon group which is a C₆-C₂₀ alicyclic hydrocarbon group selected from the group consisting of 2-methyl-2-adamantyl, 2-ethyl-2-adamantyl, 2-propyl-2-adamantyl, 8-methyl-8-tricyclodecyl, and 8-ethyl-8-tricyclodecyl, and R₅ is a C₄-C₂₀ acid-labile ester group which is a C₆-C₂₀ acid-labile alicyclic hydrocarbon ester group selected from the group consisting of 2-methyl-2-adamantyl ester, 2-ethyl-2-adamantyl ester, 2-propyl-2-adamantyl ester, 8-methyl-8-tricyclodecyl ester, and 8-ethyl-8-tricyclodecyl ester.

21. A resist composition according to claim 11, wherein the PAG is selected from the group consisting of triarylsulfonium salt, diaryliodonium salt, sulfonate, and mixtures thereof.

22. A resist composition according to claim 11, further consisting essentially of about 0.01 to about 2.0 wt % by weight based on the weight of the photosensitive polymer of an organic base.

23. A resist composition according to claim 22, wherein said organic base is selected from the group consisting of triethylamine, triisobutylamine, triisooctylamine, triisodecylamine, diethanolamine, triethanolamine, and mixtures thereof.
